(19) United States
(12) Patent Application Publication
(10) Pub. No.: US 2015/0061076 A1
(43) Pub. Date: Mar. 5, 2015

(54) HIGH DENSITY RESISTOR

(71) Applicant: International Business Machines Corporation, Armonk, NY (US)

(72) Inventors: Kangguo Cheng, Schenectady, NY (US); Bruce B. Doris, Slingerlands, NY (US); Ali Khakifirooz, Mountain View, CA (US); Alexander Reznicek, Troy, NY (US)

(73) Assignee: International Business Machines Corporation, Armonk, NY (US)

(21) Appl. No.: 14/011,208

(22) Filed: Aug. 27, 2013

(51) Int. Cl. H01L 27/08; H01L 49/02

(52) U.S. Cl. CPC H01L 27/0802; H01L 28/24
USPC 257/538; 438/382

(57) ABSTRACT

At least one three dimensional semiconductor fin is formed from a top semiconductor material of a substrate. A dielectric material is formed along vertical sidewalls and an upper surface of the at least one three dimensional semiconductor fin. A polysilicon resistor is formed on exposed surfaces of the dielectric material and surrounding the at least one semiconductor fin. An interconnect dielectric material is formed above the polysilicon resistor. The interconnect dielectric material has at least one contact structure that extends through the interconnect dielectric to an upper surface of the polysilicon resistor.

### BACKGROUND

The present application relates to passive semiconductor devices and methods of forming the same. More particularly, the present application relates to polysilicon resistors that are located upon a semiconductor fin and methods of forming such polysilicon resistors.

Resistors are passive devices that have electrical resistance associated therewith. Resistors can be employed in an electrical device for protection, operation and/or current control. As such, resistors play an important role in current analog and digital circuit designs.

Different types of resistors such as polysilicon resistors and diffusion resistors are available. Polysilicon resistors usually offer higher sheet resistance and are preferred when there is a need for higher resistor values. Typical sheet resistivity of prior art polysilicon resistors is from 500 ohms/sq to 1000 ohms/sq and usually the sheet resistivity does not scale with technology scaling. The only means that is currently available to reduce the footprint of a polysilicon resistor is to reduce the width of the resistor. However, for lithographic reasons and to minimize the resistor variation, the width is not significantly scaled from node to node. As such, there is a need to increase the area efficiency of polysilicon resistors.

### SUMMARY

At least one three dimensional semiconductor fin is formed from a top semiconductor material of a substrate. A dielectric material is formed along vertical sidewalls and an upper surface of the at least one three dimensional semiconductor fin. A polysilicon resistor is formed on exposed surfaces of the dielectric material and surrounding the at least one semiconductor fin. An interconnect dielectric material is formed above the polysilicon resistor. The interconnect dielectric material has at least one contact structure that extends through the interconnect dielectric to an upper surface of the polysilicon resistor.

In one aspect of the present application, various methods are provided for forming a polysilicon resistor atop a three dimensional semiconductor fin. In one embodiment of the present application, the method may include forming at least one semiconductor fin having a bottom surface in direct contact with a first portion of an upper surface of a buried insulator layer of a semiconductor-on-insulator substrate. Next, a dielectric material can be deposited on other portions of the upper surface of the buried insulator and on vertical sidewalls and an upper surface of the at least one semiconductor fin. After forming the dielectric material, a polysilicon resistor is formed on an upper surface of the dielectric material and around the at least one semiconductor fin. Next, an interconnect dielectric material is provided on an upper surface of the polysilicon resistor and between each semiconductor fin, wherein the interconnect dielectric material includes at least one contact structure extending from an upper surface of the interconnect dielectric material to a portion of the upper surface of the polysilicon resistor that is positioned at a footprint of the at least one semiconductor fin.

In another embodiment of the present application, the method includes forming at least one semiconductor fin from a bulk semiconductor substrate. Next, an isolation region is provided on each recessed surface of the bulk semiconductor substrate that is located at a footprint of the at least one semiconductor fin. After forming the isolation structure, a dielectric material can be deposited on an upper surface of each isolation structure and on vertical sidewalls and an upper surface of the at least one semiconductor fin. After forming the dielectric material, a polysilicon resistor is formed on an upper surface of the dielectric material and around the at least one semiconductor fin. Next, an interconnect dielectric material is provided on an upper surface of the polysilicon resistor and between each semiconductor fin, wherein the interconnect dielectric material includes at least one contact structure extending from an upper surface of the interconnect dielectric material to a portion of the upper surface of the polysilicon resistor that is positioned at a footprint of the at least one semiconductor fin.

In another aspect of the present application, a semiconductor structure is provided. Specifically, the semiconductor structure of the present application includes at least one semiconductor fin extending from a surface of a substrate. The semiconductor structure of the present application further includes a dielectric material located on vertical sidewalls and an upper surface of each semiconductor fin, and a polysilicon resistor located on an exposed surface of the dielectric material and adjacent to the vertical sidewalls and the upper surface of each semiconductor fin.

### BRIEF DESCRIPTION OF THE DRAWINGS

FIG. 1 is a cross sectional view of a first exemplary semiconductor structure including, from bottom to top, a handle substrate, a buried insulator layer and a semiconductor layer that can be used in accordance with an embodiment of the present application.

FIG. 2 is a cross sectional view of the first exemplary semiconductor structure of FIG. 1 after forming at least one semiconductor fin by patterning the semiconductor layer.

FIG. 3 is a cross sectional view of the first exemplary semiconductor structure of FIG. 3 after forming a dielectric material on exposed portions of the buried insulator layer and on vertical sidewalls and an upper surface of the at least one semiconductor fin.

FIG. 4 is a cross sectional view of the first exemplary semiconductor structure of FIG. 3 after forming a polysilicon resistor on an upper surface of the dielectric material and around the at least one semiconductor fin.

FIG. 5 is a cross sectional view of the first exemplary semiconductor structure of FIG. 4 after forming an interconnect dielectric material on an upper exposed surface of the polysilicon resistor and between each semiconductor fin, wherein the interconnect dielectric material includes at least one contact structure that extends to an upper surface of the polysilicon resistor.

FIG. 6 is a cross sectional view of a second exemplary semiconductor structure including, from bottom to top, a handle substrate, a buried insulator layer, a semiconductor layer and a hard mask layer that can be used in accordance with another embodiment of the present application.

FIG. 7 is a cross sectional view of the second exemplary semiconductor structure of FIG. 6 after forming at least one hard mask capped semiconductor fin by patterning the hard mask layer and the semiconductor layer.

FIG. 8 is a cross sectional view of the second exemplary semiconductor structure of FIG. 7 after forming at least one dielectric material, forming a polysilicon resistor and forming an interconnect dielectric material that includes at least one contact structure that extends to an upper surface of the polysilicon resistor.

FIG. 9 is a cross sectional of a third exemplary semiconductor structure which includes at least one semiconductor fin extending upward from a recessed surface of a bulk semiconductor substrate in accordance with a yet further embodiment of the present application.

FIG. 10 is a cross sectional of the third exemplary semiconductor structure of FIG. 9 after forming an isolation structure on each exposed portion of the recessed surface of the bulk semiconductor substrate.

FIG. 11 is a cross sectional of the third exemplary semiconductor structure of FIG. 10 after forming a dielectric material on upper surface of each isolation structure and on vertical sidewalls and an upper surface of the at least one semiconductor fin.

FIG. 12 is a cross sectional of the third exemplary semiconductor structure of FIG. 11 after forming a polysilicon resistor on an upper surface of the dielectric material and around the at least one semiconductor fin.

FIG. 13 is a cross sectional of the third exemplary semiconductor structure of FIG. 12 after forming an interconnect dielectric material on an upper exposed surface of the polysilicon resistor and between each semiconductor fin, wherein the interconnect dielectric material includes at least one contact structure that extends to an upper surface of the polysilicon resistor.

FIG. 14 is a cross sectional view of the third exemplary structure of FIG. 10 after reducing the thickness of each isolation structure in accordance with an even further embodiment of the present application.

FIG. 15 is a sectional view of the third exemplary structure of FIG. 14 after forming a dielectric material on upper surface of each reduced thickness isolation structure and on vertical sidewalls and an upper surface of the at least one semiconductor fin.

FIG. 16 is a cross sectional of the third exemplary semiconductor structure of FIG. 15 after forming a polysilicon resistor on an upper surface of the dielectric material and around the at least one semiconductor fin.

FIG. 17 is a cross sectional of the third exemplary semiconductor structure of FIG. 16 after forming an interconnect dielectric material on an upper exposed surface of the polysilicon resistor and between each semiconductor fin, wherein the interconnect dielectric material includes at least one contact structure that extends to an upper surface of the polysilicon resistor.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

Prior art polysilicon resistors are planar structures usually formed over a shallow trench isolation region. In some instances, prior art polysilicon resistors can be formed over the active area and isolated from the active area by a dielectric material. Typical sheet resistivity of prior art planar polysilicon resistors is from 500 ohms/sq to 1000 ohms/sq and usually the sheet resistivity does not scale with technology scaling. As such, there is a need to provide polysilicon resistors that have an increase in area efficiency.

In some embodiments, the present application provides non-planar polysilicon resistors having the same resistor characteristics as a planar polysilicon resistor but at less space. In other embodiments, the present application provides non-planar polysilicon resistors having greater resistor characteristics as compared to a planar polysilicon resistor even through the non-planar polysilicon resistors of the present application take up about the same space as a prior art polysilicon resistor.

Notably, the present application provides a semiconductor structure including a polysilicon resistor located adjacent to vertical sidewalls and atop an upper surface of a semiconductor fin. One difference between the three-dimensional resistor structure of the present application and prior art structures containing planar polysilicon resistors is that by forming the polysilicon around the vertical sidewalls and atop an upper surface of a semiconductor fin, the resistance per footprint is significantly increased without the need to change the doping or width of the polysilicon resistor.

One requirement to obtain the three dimensional resistor structure and benefit from area efficiency is that the polysilicon resistor is not pinched off in the spaces between semiconductor fins. As such, the space between each semiconductor fin in the resistor area needs to be larger than the thickness of the polysilicon resistor. In some cases, this can be achieved by removing some of the semiconductor fins from the resistor area.

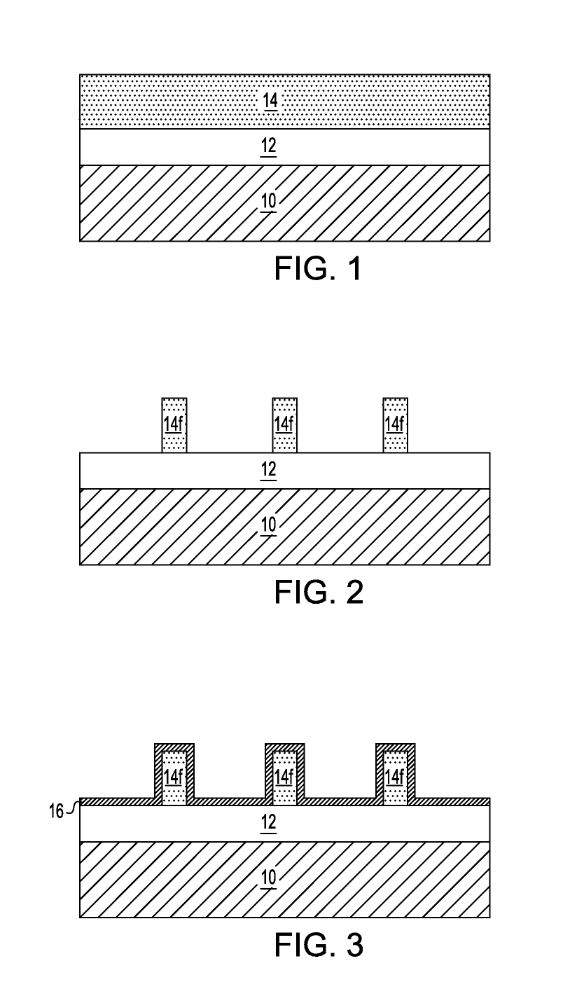

Referring to FIG. 1, there is illustrated a semiconductor structure including, from bottom to top, a handle substrate 10, a buried insulator layer 12 and a semiconductor layer 14 that can be used in accordance with an embodiment of the present application. The semiconductor structure shown in FIG. 1 can be referred to herein as a semiconductor-on-insulator substrate. The handle substrate provides mechanical support for the buried insulator layer and the semiconductor layer. It is noted that within the various drawings of the present application only a resistor area is shown. Other device areas are present and would be located to the left and/or right of the resistor area that is illustrated in the drawings of the present application. By way of an example, an area containing finFET devices could be located to the left and/or right of the resistor area shown in the drawings of the present application.

In some embodiments of the present application, the handle substrate 10 and the semiconductor layer 14 of the semiconductor structure shown in FIG. 1 may comprise a same, or different, semiconductor material. The term “semiconductor” as used herein in connection with the semiconductor material of the handle substrate 10 and the semiconductor layer 14 denotes any semiconductor material including, for example, Si, Ge, SiGe, SiC, SiGeC, and III/V compound semiconductors such as, for example, InAs, GaAs, or InP. Multilayers of these semiconductor materials can also be used as the semiconductor material of the handle substrate 10 and the semiconductor layer 14. In one embodiment, the handle substrate 10 and the semiconductor layer 14 are both comprised of silicon. In some embodiments, the handle substrate 10 is a non-semiconductor material including, for example, a dielectric material and/or a conductive material. In yet other embodiments the handle substrate 10 can be omitted and a substrate including an insulator layer and a semiconductor layer can be used as the semiconductor structure shown in FIG. 1.

In some embodiments, the handle substrate 10 and the semiconductor layer 14 may have the same or different crystal orientation. For example, the crystal orientation of the handle substrate 10 and/or the semiconductor layer 14 may be {100}, {110}, or {111}. Other crystallographic orientations besides those specifically mentioned can also be used in the present application. The handle substrate 10 and/or the semiconductor layer 14 may be a single crystalline semiconductor material, a polycrystalline material, or an amorphous material. Typically, at least the semiconductor layer 14 is a single crystalline semiconductor material.

The buried insulator layer 12 may be a crystalline or non-crystalline oxide or nitride. In one embodiment, the buried insulator layer 12 is an oxide such as, for example, silicon dioxide. The buried insulator layer 12 may be continuous or it may be discontinuous. When a discontinuous buried insulator region is present, the insulator region exists as an isolated island that is surrounded by semiconductor material.

The semiconductor structure shown in FIG. 1 may be formed utilizing standard processes including for example, SIMOX (separation by ion implantation of oxygen) or layer transfer. When a layer transfer process is employed, an optional thinning step may follow the bonding of two semiconductor wafers together. The optional thinning step reduces the thickness of the semiconductor layer to a layer having a thickness that is more desirable.

The thickness of semiconductor layer 14 is typically from 10 nm to 100 nm, with a thickness from 50 nm to 70 nm being more typical. Other thicknesses that are greater than and lesser than the aforementioned thickness ranges can also be used for the semiconductor layer 14. In some embodiments, a thinning step such as, for example, planarization or etching can be used to reduce the thickness of semiconductor layer 14 to a value within a desired thickness range mentioned above. The buried insulator layer 12 typically has a thickness from 1 nm to 200 nm, with a thickness from 100 nm to 150 nm being more typical. Other thicknesses that are greater than and lesser than the aforementioned thickness ranges can also be used for the buried insulator layer 12. The thickness of the handle substrate 10 is inconsequential to the present application.

The semiconductor layer 14 may be doped, undoped (i.e., intrinsic) or contain doped and undoped regions therein. Each doped region within the semiconductor material 14 may have the same, or they may have different conductivities and/or doping concentrations. The doped regions that are present in the semiconductor layer 14 can be formed by an ion implantation process or gas phase doping. When doped, the semiconductor layer 14 may have a dopant concentration from 1.0×10¹⁴/cm³ to 1.0×10¹⁷/cm³.

Referring now to FIG. 2, there is illustrated the first exemplary semiconductor structure of FIG. 1 after forming at least one semiconductor fin 14f by patterning the semiconductor layer 14. In the drawings, a plurality of semiconductor fins 14f are formed each having a same height and same width. As shown, each semiconductor fin 14f has a bottom surface that is located directly on a portion of the buried insulator layer 12. In the embodiment that is illustrated by the first exemplary semiconductor structure shown in FIG. 2, each semiconductor fin 14f that is formed has an upper surface that is bare. The upper surfaces of each semiconductor fin 14f are typically coplanar with each other.

In one embodiment of the present application, active semiconductor fins (not shown) that are formed are spaced apart from its nearest neighboring semiconductor fin by a pitch (i.e., fin pitch=fin width plus gap between fins) from 15 nm to 100 nm. The fin spacing in the resistor area (passive device region shown in the drawings) needs to be larger than 60 nm to avoid pinch off of the deposited layers. Depending on starting fin pitch, one, two or more fins need to be removed by methods known in the art (e.g., mask and reactive ion etching) to fabricate the required larger fin pitch for the passive device region in which a polysilicon resistor is to be formed.

Also, each semiconductor fin 14f that is formed is oriented parallel to each other. Further each semiconductor fin 14f that is formed comprises a same semiconductor material as that of semiconductor material 14 described above.

The semiconductor structure that is illustrated in FIG. 2 can be can be formed by lithography and etching. Lithography can include forming a photoresist (not shown) on the topmost surface of the semiconductor layer 14, exposing the photoresist to a desired pattern of radiation, and then developing the exposed photoresist with a conventional resist developer to provide a patterned photoresist atop the semiconductor layer 14. At least one etch is then employed which transfers the pattern from the patterned photoresist into the semiconductor layer 14 utilizing the underlying buried insulator layer 12 as an etch stop. In one embodiment, the etch used for pattern transfer may include a dry etch process such as, for example, reactive ion etching, plasma etching, ion beam etching or laser ablation. After transferring the pattern into the semiconductor layer, the patterned photoresist can be removed utilizing a conventional resist stripping process such as, for example, ashing. To get the initial tight fin pitch required for active devices on the same wafer, fin etching can be performed utilizing a sidewall image transfer (SIT). Sidewall image transfer (SIT) provides sub-lithographic patterns by doubling the density of patterns. In a SIT process, sidewalls are formed around one or more mandrel structures on a surface. The mandrels are then removed, leaving the sidewalls standing free on the surface. This allows the sidewalls themselves to be used to be used as a mask for further processing, allowing the creation of features with widths substantially smaller than the minimum size allowed by a given lithographic process.

As used herein, a “semiconductor fin” refers to a contiguous structure including a semiconductor material and including a pair of vertical sidewalls that are parallel to each other. As used herein, a surface is “vertical” if there exists a vertical plane from which the surface does not deviate by more than three times the root mean square roughness of the surface. In the present application, the semiconductor fins 14f are provided in an area of a structure in which a polysilicon resistor(s) will be subsequently formed. As such, each semiconductor fin 14f that is processed within the resistor will not include, or be processed to have, an active channel region, a source region and a drain region within any part of the semiconductor fin 14f; this is also applicable for semiconductor fins 50f that are formed in a bulk semiconductor substrate.

In one embodiment of the present application, each semiconductor fin 14f has a height from 10 nm to 100 nm, and a width from 4 nm to 30 nm. In another embodiment of the present application, each semiconductor fin 14f has a height from 15 nm to 50 nm, and a width from 5 nm to 12 nm.

Referring now to FIG. 3, there is illustrated the first exemplary semiconductor structure of FIG. 2 after forming a dielectric material 16 on exposed portions of the buried insulator layer 12 and on vertical sidewalls and an upper surface of the at least one semiconductor fin 14f. The dielectric material 16 is a contiguous, conformal dielectric material that lines each exposed surface of the first exemplary semiconductor structure shown in FIG. 2.

The dielectric material 16 is used in the present application to provide isolation between each semiconductor fin 14f and a subsequently formed polysilicon resistor. The dielectric material 16 may comprise a same or different dielectric material than buried insulator layer 12. In one example, the dielectric material 16 can be a semiconductor oxide (e.g., SiO₂), a semiconductor nitride (e.g., SiN), and/or semiconductor oxynitride (e.g., SiON). In another example, the dielectric material 16 can be a high k material having a dielectric constant greater than silicon dioxide. Exemplary high k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered dielectric structure comprising different gate dielectric materials, e.g., silicon dioxide, and a high k gate dielectric can be used as dielectric material 16.

The dielectric material 16 can be formed by any deposition technique including, for example, chemical vapor deposition (CVD), plasma enhanced chemical vapor deposition (PECVD), physical vapor deposition (PVD), sputtering, or atomic layer deposition. In some embodiments, a thermal growth process can be used in forming the dielectric material 16. In one embodiment of the present application, the dielectric material 16 can have a thickness in a range from 1 nm to 10 nm. Other thicknesses that are lesser than or greater than the aforementioned thickness range can also be employed for the dielectric material 16.

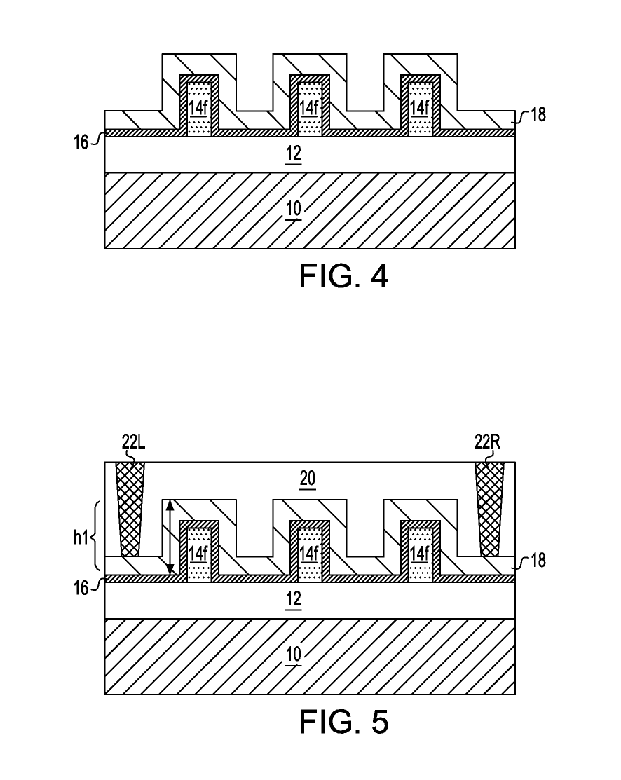

Referring now to FIG. 4, there is illustrated the first exemplary semiconductor structure of FIG. 3 after forming a polysilicon resistor 18 on an upper surface of the dielectric material 16 and around the at least one semiconductor fin 14f. In one embodiment, the polysilicon resistor 18, which includes a conformal layer of polysilicon, can be non-doped (i.e., intrinsic). In another embodiment, the polysilicon resistor 18, which includes a conformal layer of polysilicon, can be doped.

In some embodiments and in which the polysilicon resistor 18 is doped, doping can be achieved by utilizing one of ion implantation, gas phase doping or out diffusion from a dopant source material that is subsequently formed on the polysilicon resistor 18. In other embodiments, the doping of the polysilicon resistor 18 can be achieved utilizing an in-situ deposition process in which at least one dopant is used in conjunction with a silicon precursor that forms the polysilicon resistor 18. When doped, the polysilicon resistor can include a p-type dopant (and thus a p-type polysilicon resistor is provided) or an n-type dopant (and thus an n-type polysilicon resistor is provided). When a p-type polysilicon resistor is provided, one of boron, aluminum, gallium and indium can be present in the polysilicon resistor 18. When an n-type polysilicon resistor is provided, one of antimony, arsenic and phosphorous can be present in the polysilicon resistor 18.

In one embodiment of the present application and when the polysilicon resistor 18 includes a dopant, the dopant can be present in the polysilicon resistor 18 in a concentration from 1×10¹⁸ atoms/cm³ to 1×10²¹ atoms/cm³. In another embodiment of the present application and when the polysilicon resistor 18 includes a dopant, the dopant can be present in the polysilicon resistor 18 in a concentration from 1×10¹⁸ atoms/cm³ to 2×10²⁰ atoms/cm³. Other dopant concentrations can be used as well. It is noted that the doping concentration can depend on the size of the polysilicon resistor and a desired resistor value.

The polysilicon resistor 18 can be formed by a deposition process including, for example, chemical vapor deposition (CVD), plasma enhanced chemical vapor deposition (PECVD), physical vapor deposition (PVD), sputtering, atomic layer deposition (ALD) or other like deposition processes. In one embodiment, the polysilicon resistor 18 that is located atop the upper surface of each semiconductor fin and atop the dielectric material that is located at the footprint of each semiconductor fin has a same thickness which can range from 1 nm to 100 nm. Other thicknesses that are lesser than or greater than the aforementioned thickness range can also be employed for the polysilicon resistor.

Referring now to FIG. 5, there is illustrated the first exemplary semiconductor structure of FIG. 4 after forming an interconnect dielectric material 20 on an upper exposed surface of the polysilicon resistor 18 and between each semiconductor fin 14f. As is illustrated the interconnect dielectric material 18 includes at least one contact structure 22L, 22R that extends to an upper surface of the polysilicon resistor 18. That is, a bottom surface of each contact structure 22L, 22R is in contact with a portion of the upper surface of the polysilicon resistor 18. Each contact structure 22L, 22R also has an upper surface that is coplanar with an upper surface of the interconnect dielectric material 20.

The interconnect dielectric material 20 may comprise any interlevel or intralevel dielectric including inorganic dielectrics or organic dielectrics. Some examples of suitable dielectrics that can be used as the interconnect dielectric material 20 include, but are not limited to, SiO₂, doped glass, silsesquioxanes, C doped oxides (i.e., organosilicates) that include atoms of Si, C, O and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like.

The interconnect dielectric material 20 typically has a dielectric constant that is about 4.0 or less, with a dielectric constant of about 2.8 or less being more typical. All dielectric constants mentioned herein are relative to a vacuum, unless otherwise noted. The interconnect dielectric material 20 has an upper surface that is located above an upper surface of the polysilicon resistor 18 that is present atop the upper surface of each semiconductor fin 14f. In one embodiment of the present application, the thickness of the interconnect dielectric material 20 can be from 50 nm to 1000 nm. Other thicknesses that are greater than or lesser than the aforementioned thickness range can also be employed for the interconnect dielectric material 20. The interconnect dielectric material 20 can be formed utilizing a deposition process including, for example, chemical vapor deposition, plasma enhanced chemical vapor deposition, evaporation or spin-on coating.

Following the formation of the interconnect dielectric material 20, the interconnect dielectric material 20 can be patterned by lithography and etching to form at least one contact opening that extends from an upper surface of the interconnect dielectric material 20 to an upper surface of the polysilicon resistor 18 which is typically not present directly atop each polysilicon fin 14f. Each contact opening that is formed may have substantially vertical sidewalls or the sidewalls of each contact opening may have some tapering associated therein. In one embodiment, the width of each contact opening at a bottom portion of the contact opening is less than the width at an upper portion of the contact opening.

A metal semiconductor alloy is first formed in the contact opening utilizing processes well known in the art. For example, a silicide process can be used to form a metal silicide in each contact opening. The metal semiconductor alloy is not specifically shown in the drawings, however the metal semiconductor alloy is located between the conductive material (to be subsequently formed) and a surface of the polysilicon resistor 18. The metal semiconductor alloy could be represented by a lower portion of conductive structure 22L, 22R which directly contacts a portion of the polysilicon resistor 18. After forming the metal semiconductor alloy, a conductive material is then deposited filling each contact opening. The conductive material that is deposited may include for example, at least one of copper, tungsten, and aluminum. In one embodiment, the conductive material that fills each contact opening comprises copper or a copper alloy such as, for example, a copper-aluminum alloy. The conductive material may be formed by a deposition process including chemical vapor deposition (CVD), plasma enhanced chemical vapor deposition (PECVD), sputtering, or chemical solution deposition. Alternatively, a plating process that fills each contact opening from the bottom upwards can be used. After depositing the conductive material, a planarization process such as, for example, chemical mechanical polishing (CMP) and/or grinding, can be employed to remove portions of the conductive material that extends above the mouth of each contact opening that is formed into interconnect dielectric material 20. The above steps provide contact structure(s) 22L, 22R into interconnect dielectric material 20.

Notably, the first exemplary semiconductor structure shown in FIGS. 4-5 includes at least one semiconductor fin 14f extending from a surface of a substrate (i.e., buried insulator layer 12 of a semiconductor-on-insulator substrate). The semiconductor structure of the present application which is illustrated in FIGS. 4-5 further includes a dielectric material 16 located on vertical sidewalls and an upper surface of each semiconductor fin 14f, and a polysilicon resistor 18 located on an exposed surface of the dielectric material 16 and adjacent to the vertical sidewalls and the upper surface of each semiconductor fin 14f. In the first exemplary semiconductor structure shown in FIGS. 4-5, the polysilicon resistor 18 has a height h1 that is greater than a height of the at least one semiconductor fin 14f.

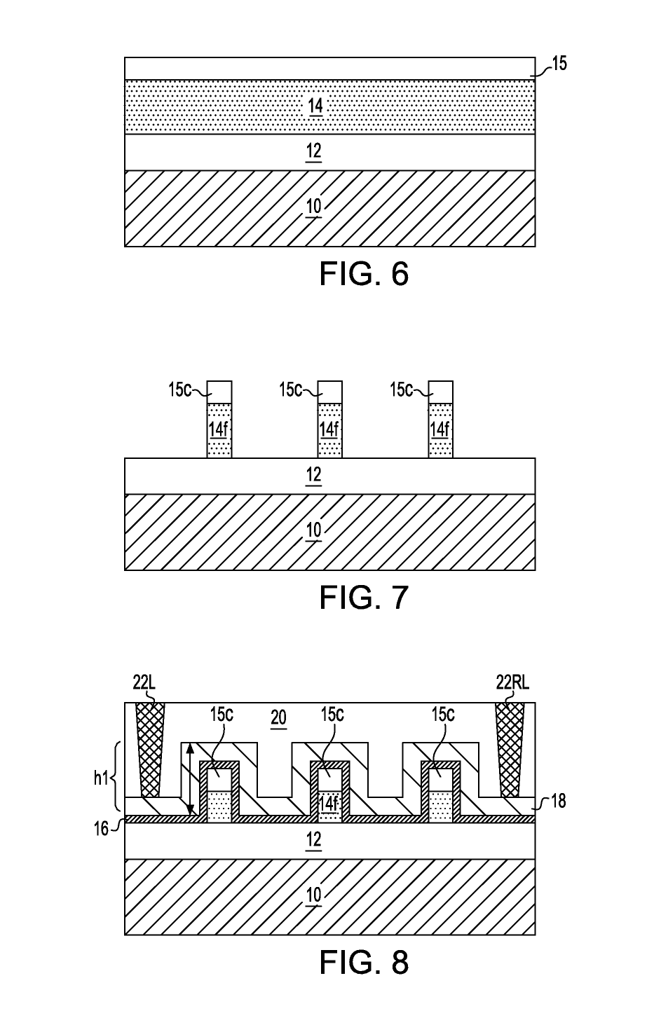

Referring now to FIG. 6, there is illustrated a second exemplary semiconductor structure including, from bottom to top, a handle substrate 10, a buried insulator layer 12, a semiconductor layer 14 and a hard mask layer 15 that can be used in accordance with another embodiment of the present application. Elements 10, 12 and 14 of the second exemplary semiconductor structure are the same as elements 10, 12 and 14 described above in regard to the first exemplary semiconductor structure shown in FIG. 1 of the present application. As such, the description above with respect to elements 10, 12 and 14 apply equally well for this embodiment of the present application and thus the description of elements 10, 12 and 14 made above is incorporated herein by reference.

In addition to the handle substrate 10, the buried insulator 12 and the semiconductor layer 14, the secondary exemplary semiconductor structure shown in FIG. 6 further includes a hard mask layer 15 formed as a blanket layer on an upper surface of the semiconductor layer 14. The hard mask layer 15 is employed in this embodiment of the present application to form a hard mask cap on an upper surface of each semiconductor fin 14f, which serves to increase the effective height, i.e., the length, of the polysilicon resistor to be subsequently formed. The height of the hard mask layer 15 (which also equals the height of the subsequent formed hard mask cap 15c) can be used in the present application to vary the resistor value. Other means for varying the resistor value in the present application and as discussed above, is by doping the polysilicon resistor. A yet further means of varying the resistor value can be achieved by the number of fins per each polysilicon resistor.

The hard mask layer 15 that can be employed in this embodiment of the present application may include a dielectric oxide, a dielectric nitride, a dielectric oxynitride or any multilayered combination thereof. In one embodiment, the hard mask layer 15 is a dielectric oxide such as silicon dioxide, while in another embodiment the hard mask layer 15 is a dielectric nitride such as silicon nitride. The hard mask layer 15 can be formed utilizing a deposition process including, for example, chemical vapor deposition (CVD), plasma enhanced chemical vapor deposition (PECVD), chemical solution deposition, evaporation, or physical vapor deposition (PVD). Alternatively, the hard mask layer 15 may be formed by one of thermal oxidation, and thermal nitridation. The thickness of the hard mask layer 15 employed in the present application may vary depending on the material of the hard mask layer 15 itself as well as the technique used in forming the same. Typically, and in one embodiment, the hard mask layer 15 has a thickness from 5 nm to 100 nm. Other thicknesses that are greater than or lesser than the aforementioned thickness range can also be used for the thickness of the hard mask layer 15.

Referring now to FIG. 7, there is illustrated the second exemplary semiconductor structure of FIG. 6 after forming at least one hard mask capped semiconductor fin (i.e., at least one semiconductor fin 14f that includes a hard mask cap 15c located on an upper surface of the semiconductor fin 14f). As shown, the vertical edges of the hard mask cap 15c are vertically coincident with the vertical edges of the semiconductor fin 14f.

The least one hard mask capped semiconductor fin (14f, 15c) can be formed by patterning the hard mask layer 15 and the semiconductor layer 14 by lithography and etching. The lithographic step used in providing the structure shown in FIG. 7 is the same as the lithographic step mentioned above in forming the first exemplary semiconductor structure shown in FIG. 2 of the present application. The etching step used in providing the second exemplary semiconductor structure shown in FIG. 7 is also the same as that described above in forming the first exemplary semiconductor structure shown in FIG. 2. In one embodiment, STI can be used to etch the fins. In some embodiments, a single etch can be used in providing the second exemplary structure shown in FIG. 7. In other embodiments, multiple etching steps utilizing different etchants can be used in providing the second exemplary structure shown in FIG. 7. In this embodiment of the present application, the pattern from the exposed and developed photoresist is first transferred into the hard mask layer 15 and then into the underlying semiconductor layer 14. In some embodiments, the exposed and developed photoresist can be removed from the structure immediately after transferring the pattern into the hard mask layer 15. In other embodiments, the exposed and developed photoresist can be removed after transferring the pattern into both the hard mask layer 15 and the underlying semiconductor layer 14.

Referring now to FIG. 8, there is illustrated the second exemplary semiconductor structure of FIG. 7 after forming at least one dielectric material 16, forming a polysilicon resistor 18 and forming an interconnect dielectric material 20 that includes at least one contact structure 22L, 22R that extends to an upper surface of the polysilicon resistor 18. The second exemplary semiconductor structure shown in FIG. 8 can be provided utilizing the various materials and processing steps described above and shown in FIG. 3 (at least one dielectric material 16), FIG. 4 (polysilicon resistor 18) and FIG. 5 (interconnect dielectric material with contact structures 22L, 22R) of the present application.

Notably, the second exemplary semiconductor structure shown in FIG. 8 includes at least one semiconductor fin 14f extending from a surface of a substrate (i.e., buried insulator layer 12 of a semiconductor-on-insulator substrate). Each semiconductor fin 14f includes a hard mask cap 15c located on an upper surface thereof. The semiconductor structure of the present application which is illustrated in FIG. 8 further includes a dielectric material 16 located on vertical sidewalls and atop an upper surface of each semiconductor fin 14f, and a polysilicon resistor 18 located on an exposed surface of the dielectric material 16 and adjacent to the vertical sidewalls and the upper surface of each semiconductor fin 14f. In the second exemplary semiconductor structure shown in FIG. 8, the polysilicon resistor has a height h1 that is greater than a height of the at least one semiconductor fin and a thickness of the hard mask cap 15c.

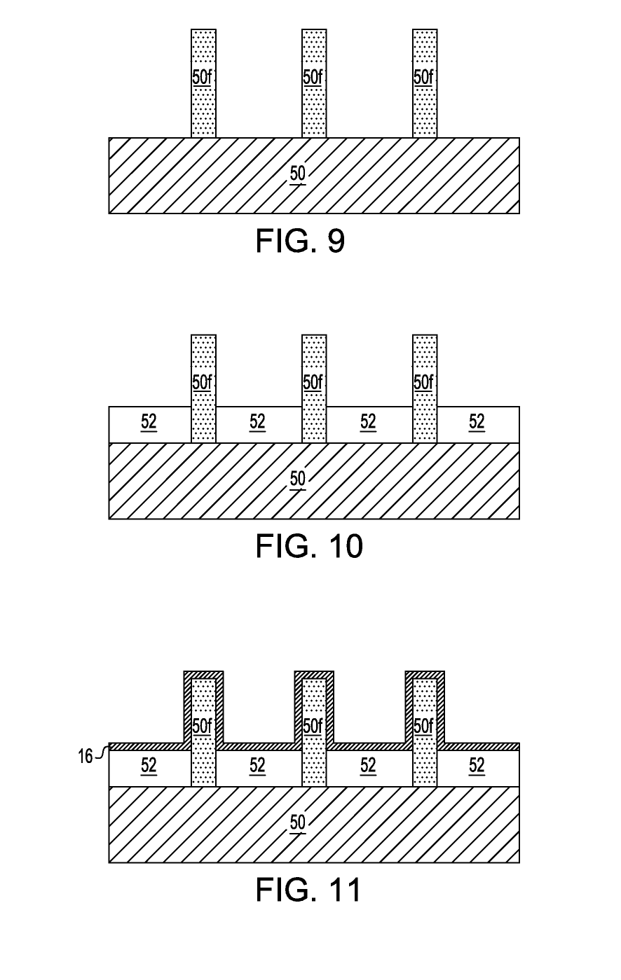

Referring now to FIG. 9, there is illustrated a third exemplary semiconductor structure which includes at least one semiconductor fin 50f extending upward from a recessed surface of a bulk semiconductor substrate 50 in accordance with a yet further embodiment of the present application. In some embodiments (not shown), a hard mask cap can be located on an upper surface of each semiconductor fin 50f.

The third exemplary semiconductor structure shown in FIG. 9 can be formed by first providing a bulk semiconductor substrate. The term “bulk semiconductor substrate” denotes a substrate that is entirely made from a semiconductor material. The semiconductor material that comprises the bulk semiconductor substrate 50 may comprise at least one of the semiconductor materials mentioned above in connection with semiconductor layer 14. After providing the bulk semiconductor substrate, a hard mask layer (not shown) can be formed on an upper surface of the bulk semiconductor material. Next, at least one semiconductor fin 50f can be formed by lithography and etching. The lithographic and etching processes used in providing the third exemplary semiconductor structure shown in FIG. 9 are the same as that used in providing the first exemplary semiconductor structure shown in FIG. 2.

Each semiconductor fin 50f is of unitary construction with the bulk semiconductor substrate 50 and is comprised of a semiconductor material that forms an upper portion of the bulk semiconductor substrate 50. In this embodiment, there is no interface present between the semiconductor fin 50f and the remaining bulk semiconductor substrate. The semiconductor surface of the bulk semiconductor substrate 50 that is present at the footprint of each semiconductor fin 50f is referred to herein as a recessed surface since the etch used in forming each semiconductor fin 50f removes a portion of the original bulk semiconductor substrate.

Referring now to FIG. 10, there is illustrated the third exemplary semiconductor structure of FIG. 9 after forming an isolation structure 52 on each exposed portion of the recessed surface of the bulk semiconductor substrate 50 and at a footprint of each semiconductor fin 50f.

Each isolation structure 52 that can be formed has an upper surface that is located beneath and not coplanar with an upper surface of each semiconductor fin 50f. Also, each isolation structure 52 has a sidewall surface that contacts a lower portion of a vertical sidewall of each semiconductor fin 50f, and a bottom surface that contacts a semiconductor material surface of the bulk semiconductor substrate 50. In one embodiment of the present application, the height of each isolation structure 52 is from 10 nm to 100 nm, and the width of each isolation structure 52 is from 20 nm to 100 nm. In another embodiment of the present application, the height of each isolation structure 52 is from 15 nm 50 nm, and the width of each isolation structure 52 is from 25 nm to 80 nm. Each isolation structure 52 can be formed by first depositing a trench dielectric oxide, followed by chemical mechanical planarization and then an etch back process can be employed. In one embodiment of the present application, each isolation structure 52 can be formed utilizing a localized oxidation of silicon process.

Referring now to FIG. 11, there is illustrated the third exemplary semiconductor structure of FIG. 10 after forming a dielectric material 16 on upper surface of each isolation structure 52 and on vertical sidewalls and an upper surface of the at least one semiconductor fin 50f. The materials and processing used in providing the dielectric material 16 in the first exemplary semiconductor structure shown in FIG. 3 can also be used herein in providing the dielectric material in the third exemplary semiconductor structure shown in FIG. 11.

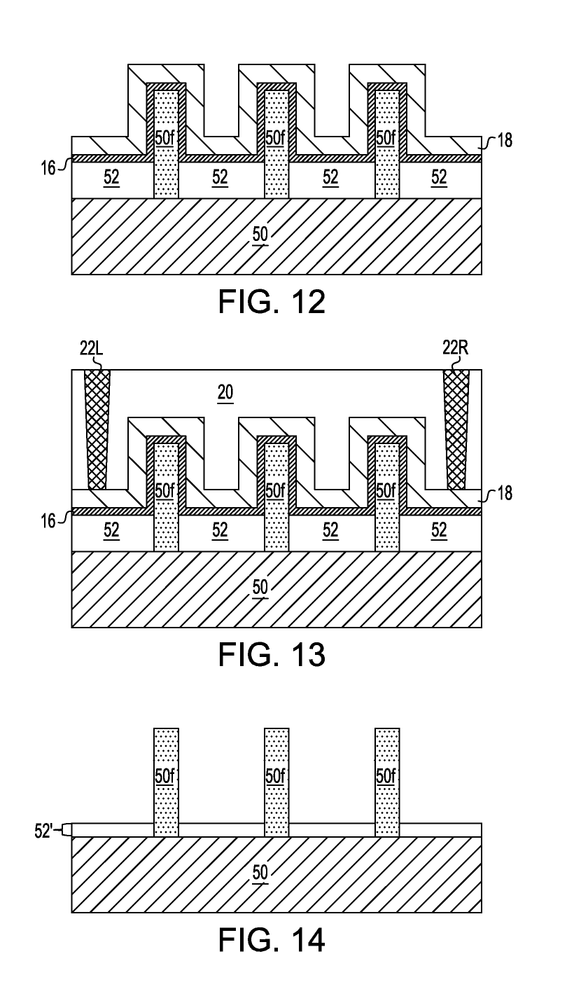

Referring now to FIG. 12, there is illustrated the third exemplary semiconductor structure of FIG. 11 after forming a polysilicon resistor 18 on an upper surface of the dielectric material 16 and around the at least one semiconductor fin 50f. The materials, optional dopants, dopant concentrations and processing used in providing the polysilicon resistor 18 in the first exemplary semiconductor structure shown in FIG. 4 can also be used herein in providing the dielectric material in the third exemplary semiconductor structure shown in FIG. 12.

Referring now to FIG. 13, there is illustrated the third exemplary semiconductor structure of FIG. 12 after forming an interconnect dielectric material 20 on an upper exposed surface of the polysilicon resistor 18 and between each semiconductor fin 20, wherein the interconnect dielectric material includes at least one contact structure that extends to an upper surface of the polysilicon resistor. The materials and processing used in providing the interconnect dielectric material 20 and the contact structures 22L, 22R to the first exemplary semiconductor structure can also be used in providing the interconnect dielectric material 20 and contact structures 22L, 22R to the third exemplary semiconductor structure of the present application.

Notably, the third exemplary semiconductor structure shown in FIGS. 12-13 includes at least one semiconductor fin 50f extending from a surface of a substrate (i.e., a remaining portion of a bulk semiconductor substrate 50). The semiconductor structure of the present application which is illustrated in FIGS. 12-13 may or may not include a hard mask cap located on an upper surface of each semiconductor fin 50f. The semiconductor structure that is shown in FIGS. 12-13 further includes a dielectric material 16 located on vertical sidewalls and atop an upper surface of each semiconductor fin 50f, and a polysilicon resistor 18 located on an exposed surface of the dielectric material 16 and adjacent to the vertical sidewalls and the upper surface of each semiconductor fin 50f. In the third exemplary semiconductor structure shown in FIGS. 12-13, a portion of the dielectric material 16 is separated the substrate (i.e., remaining portions of bulk semiconductor substrate 50) by a dielectric structure 52.

Referring now to FIG. 14, there is illustrated the third exemplary structure of FIG. 10 after reducing the thickness of each isolation structure 52 in accordance with an even further embodiment of the present application. The remaining portions of each isolation structure can be referred to herein as a reduced thickness isolation structure 52′. Although FIG. 14 illustrates the presence of a reduced thickness isolation structure 52′, the present application also contemplates an embodiment in which the entirety of each isolation structure 52 is removed. In such an embodiment in which the entirety of each isolation structure 52 is removed, a semiconductor material portion of the bulk semiconductor substrate 50 that is present at the footprint of each semiconductor fin 50f would be exposed. The complete or partial removal of the isolation structure 52 can be achieved utilizing a timed etching process such as, for example, a timed reactive ion etch, which selectively removes at least a portion of the isolation structure 52 relative to the semiconductor fins 50f.

In embodiments in which partial removal of each isolation structure 52 is performed, each reduced thickness isolation structure 52′ has a height that is less than the height of the original isolation structure 52.

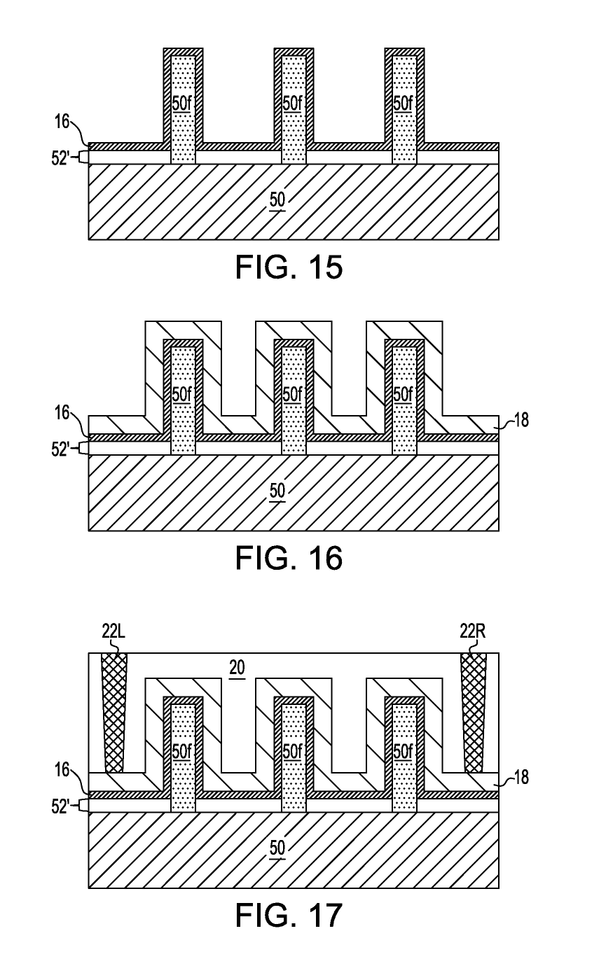

Referring now to FIG. 15, there is illustrated the third exemplary structure of FIG. 14 after forming a dielectric material 16 on upper surface of each reduced thickness isolation structure 52′ and on vertical sidewalls and an upper surface of the at least one semiconductor fin 50f. The materials and processing used in providing the dielectric material 16 in the first exemplary semiconductor structure shown in FIG. 3 can also be used herein in providing the dielectric material in the third exemplary semiconductor structure shown in FIG. 15.

Referring now to FIG. 16, there is illustrated the third exemplary semiconductor structure of FIG. 15 after forming a polysilicon resistor 18 on an upper surface of the dielectric material 16 and around each semiconductor fin 50f. The materials, optional dopants, dopant concentrations and processing used in providing the polysilicon resistor 18 in the first exemplary semiconductor structure shown in FIG. 4 can also be used herein in providing the dielectric material in the third exemplary semiconductor structure shown in FIG. 16.

Referring now to FIG. 17, there is illustrated the third exemplary semiconductor structure of FIG. 16 after forming an interconnect dielectric material 20 on an upper exposed surface of the polysilicon resistor 18 and between each semiconductor fin 50, wherein the interconnect dielectric material 20 includes at least one contact structure 22L, 22R that extends to an upper surface of the polysilicon resistor 18. The materials and processing used in providing the interconnect dielectric material 20 and the contact structures 22L, 22R to the first exemplary semiconductor structure can also be used in providing the interconnect dielectric material 20 and contact structures, 22L, 22R to the third exemplary semiconductor structure of the present application.

Notably, the third exemplary semiconductor structure shown in FIGS. 16-17 includes at least one semiconductor fin 50f extending from a surface of a substrate (i.e., a remaining portion of a bulk semiconductor substrate 50). The semiconductor structure of the present application which is illustrated in FIGS. 16-17 may or may not include a hard mask cap located on an upper surface of each semiconductor fin 50f. The semiconductor structure that is shown in FIGS. 16-17 further includes a dielectric material 16 located on vertical sidewalls and atop an upper surface of each semiconductor fin 50f, and a polysilicon resistor 18 located on an exposed surface of the dielectric material 16 and adjacent to the vertical sidewalls and the upper surface of each semiconductor fin 50f. In the third exemplary semiconductor structure shown in FIGS. 16-17, a portion of the dielectric material 16 is separated the substrate (i.e., remaining portions of bulk semiconductor substrate 50) by a reduced thickness dielectric structure 52′.

While the present application has been particularly shown and described with respect to various embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A method of forming a polysilicon resistor comprising:
forming at least one semiconductor fin having a bottom surface in direct contact with a first portion of an upper surface of a buried insulator layer of a semiconductor-on-insulator substrate;
depositing a dielectric material on other portions of said upper surface of said buried insulator and on vertical sidewalls and an upper surface of said at least one semiconductor fin;
forming a polysilicon resistor on an upper surface of said dielectric material and around said at least one semiconductor fin; and
providing an interconnect dielectric material on an upper surface of said polysilicon resistor and between each semiconductor fin, wherein said interconnect dielectric material includes at least one contact structure extending from an upper surface of said interconnect dielectric material to a portion of said upper surface of said polysilicon resistor that is positioned at a footprint of said at least one semiconductor fin.

2. The method of claim 1, wherein said at least one semiconductor fin contains a hard mask cap located on said upper surface of said at least one semiconductor fin.

3. The method of claim 1, wherein said polysilicon resistor is doped with a dopant selected from the group consisting of a p-type dopant and an-type dopant.

4. The method of claim 1, wherein said at least one semiconductor fin is void of an active channel region, a source region and a drain region.

5. The method of claim 1, wherein said polysilicon resistor has a height that is greater than a height of the at least one semiconductor fin.

6. The method of claim 2, wherein said polysilicon resistor has a height that is greater than a height of the at least one semiconductor fin and a height of said hard mask cap.

7. A method of forming a polysilicon resistor comprising:
forming at least one semiconductor fin from a bulk semiconductor substrate;
providing an isolation region on each recessed surface of said bulk semiconductor substrate that is located at a footprint of said at least one semiconductor fin;
depositing a dielectric material on an upper surface of each isolation structure and on vertical sidewalls and an upper surface of said at least one semiconductor fin;
forming a polysilicon resistor on an upper surface of said dielectric material and around said at least one semiconductor fin; and
providing an interconnect dielectric material on an upper surface of said polysilicon resistor and between each semiconductor fin, wherein said interconnect dielectric material includes at least one contact structure extending from an upper surface of said interconnect dielectric material to a portion of said upper surface of said polysilicon resistor that is positioned at a footprint of said at least one semiconductor fin.

8. The method of claim 7, wherein said at least one semiconductor fin contains a hard mask cap located on said upper surface of said at least one semiconductor fin.

9. The method of claim 7, wherein said polysilicon resistor is doped with a dopant selected from the group consisting of a p-type dopant and an-type dopant.

10. The method of claim 7, wherein said at least one semiconductor fin is void of an active channel region, a source region and a drain region.

11. The method of claim 7, wherein a portion of each isolation region is partially removed utilizing a timed etching process prior to forming said dielectric material.

12. A semiconductor structure comprising:
at least one semiconductor fin extending from a surface of a substrate;
a dielectric material located on vertical sidewalls and an upper surface of each semiconductor fin; and
a polysilicon resistor located on an exposed surface of said dielectric material and adjacent to said vertical sidewalls and said upper surface of each semiconductor fin.

13. The semiconductor structure of claim 12, wherein said at least one semiconductor fin contains a hard mask cap located on said upper surface of said at least one semiconductor fin.

14. The semiconductor structure of claim 12, wherein said polysilicon resistor is doped with a dopant selected from the group consisting of a p-type dopant and an n-type dopant.

15. The semiconductor structure of claim 12, wherein said at least one semiconductor fin is void of an active channel region, a source region and a drain region.

16. The semiconductor structure of claim 12, wherein said polysilicon resistor has a height that is greater than a height of the at least one semiconductor fin.

17. The semiconductor structure of claim 13, wherein said polysilicon resistor has a height that is greater than a height of the at least one semiconductor fin and a height of said hard mask cap.

18. The semiconductor structure of claim 12, wherein said substrate comprises a buried insulator layer of a semiconductor-on-insulator substrate.

19. The semiconductor structure of claim 12, wherein said substrate comprises a remaining portion of a bulk semiconductor substrate, and said at least one semiconductor fin is of unitary construction and comprises a same semiconductor material as said remaining portion of said bulk semiconductor substrate.

20. The semiconductor structure of claim 12, wherein an isolation structure separates a portion of said dielectric material from said substrate.
